(19) United States
(12) Patent Application Publication
(10) Pub. No.: US 2014/0367810 A1
(43) Pub. Date: Dec. 18, 2014

(54) Open Cavity Substrate in a MEMS Microphone Assembly and Method of Manufacturing the Same

(71) Applicant: Knowles Electronics, LLC, Itasca, IL (US)

(72) Inventors: Sandra Vos, East Dundee, IL (US); John B. Szczech, Schaumburg, IL (US)

(21) Appl. No.: 14/297,155

(22) Filed: Jun. 5, 2014

Related U.S. Application Data
(60) Provisional application No. 61/836,370, filed on Jun. 18, 2013.

(51) Int. Cl. B81B 3/00

(52) U.S. Cl. CPC B81B 3/0078
USPC 257/416

(57) ABSTRACT

An acoustic apparatus includes a substrate. A microelectromechanical system (MEMS) device is disposed on the substrate. The MEMS device forms a back volume between the MEMS device and the substrate. An integrated circuit disposed on the substrate. A cover is disposed on the substrate and the cover includes a port. The cover forms a cavity in which the MEMS device and the integrated circuit are disposed. The cover, substrate, MEMS device, and integrated circuit form a front volume. A filler material is disposed in the cavity to reduce an amount of the front volume that would exist in the absence of the filler material.

### CROSS REFERENCE TO RELATED APPLICATIONS

This patent claims benefit under 35 U.S.C. §119 (e) to United States Provisional Application No. 61836370 entitled “Open Cavity Substrate in MEMS Microphone Assembly and Method of Manufacturing the Same” filed Jun. 18, 2013, the content of which is incorporated herein by reference in its entirety.

### TECHNICAL FIELD

This application relates to microelectromechanical microphones and, more specifically, improving the performance characteristics of these devices.

### BACKGROUND OF THE INVENTION

MicroElectroMechanical System (MEMS) devices include microphones and speakers to mention two examples. In the case of a MEMS microphone, sound energy enters through a sound port and vibrates a diaphragm and this action creates a corresponding change in electrical potential (voltage) between the diaphragm and a back plate disposed near the diaphragm. This voltage represents the sound energy that has been received. Typically, the voltage is then transmitted to an electric circuit (e.g., an integrated circuit such as an application specific integrated circuit (ASIC)). Further processing of the signal may be performed on the electrical circuit. For instance, amplification or filtering functions may be performed on the voltage signal at the integrated circuit.

It is typically desired to have the microphone have as linear response as possible over as wide a frequency range as possible. Generally speaking, the greater the linearity, the better the performance of the microphone. Due to various factors, a resonance peak exists in the response curves of MEMS microphones. It has been extremely difficult for previous approaches to avoid the effects of the resonance peak given the size, shape, and manufacturing procedures used in previous systems.

Because of these shortcomings, previous approaches have not adequately addressed the above-mentioned problems and user dissatisfaction with these previous approaches has increased.

### BRIEF DESCRIPTION OF THE DRAWINGS

For a more complete understanding of the disclosure, reference should be made to the following detailed description and accompanying drawings wherein:

FIG. 1 comprises a side cutaway view of a microphone assembly according to various embodiments of the present invention;

FIG. 2 comprises a view of the microphone assembly of FIG. 1 looking downward with the lid removed according to various embodiments of the present invention;

FIG. 3 comprises a flowchart of a process for constructing a MEMS microphone assembly according to various embodiments of the present invention; and

FIG. 4 shows a graph showing the benefits achieved by the microphone assemblies presented herein according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

The present approaches reduce the front volume to minimize acoustic effects of the package. In these regards, an open cavity substrate (e.g., a printed circuit board (PCB)) is made without (or with) a solder mask layer on the top side of the board (either on the top shelves or the bottom of the cavity where the IC and MEMS are placed) so that the board can withstand additional processing, for example, at PCB vendor. The solder mask layer is eliminated because the wire bond pads to the IC are made on top of the plated thru-hole via using a solid via; thereby allowing wire bond to be made directly to the via or to the capture pad surrounding the plated through hole via and/or solid via. The open cavity can be large enough so that a MEMS device and an integrated circuit can be placed inside and then an epoxy is dispensed inside the cavity to “fill” the package and reduce front volume. A lid (e.g., a metal lid or printed circuit board (PCB) lid) can be soldered to the top surface or shelves of the open cavity PCB or a mesh lid (acoustic filter material) can be attached to the top surface.

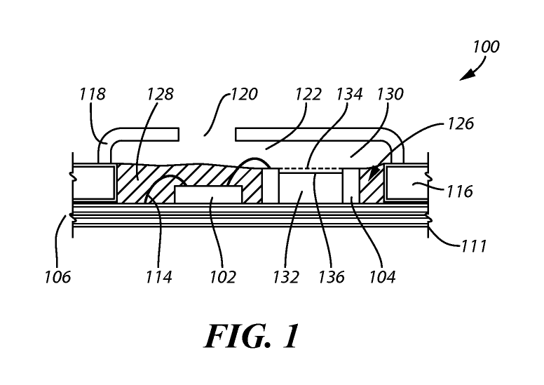

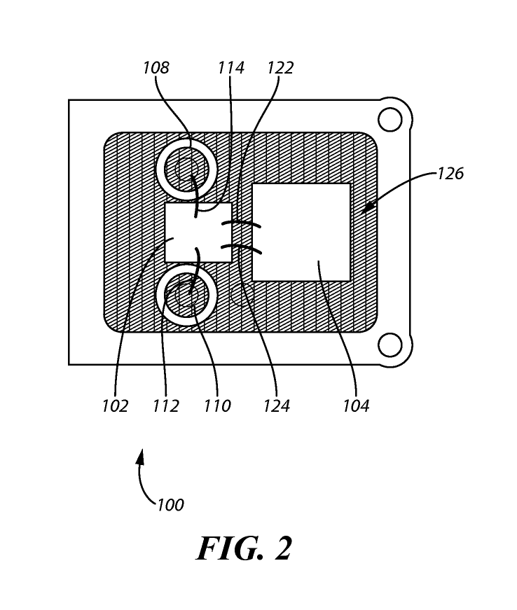

Referring now to FIG. 1 and FIG. 2, one example of a microphone assembly with improved performance is described. A microphone assembly 100 includes a microelectromechanical (MEMS) device 104 and an integrated circuit 102. The MEMS device 104 and the integrated circuit 102 are disposed on a substrate 106. The substrate 106, as is known to those skilled in the art, is constructed of multiple alternating layers of conductive and insulative materials. Conductive pads 108 and 110 form an electrical contact point on the top surface of the substrate and extend to some of the conductive layers of the substrate. Wire bonds 112, 114 extend between the integrated circuit 102 and the conductive pads 108 and 110. Alternatively, a ceramic substrate can be used.

A cavity wall 116 is formed on the top surface of the substrate 106. A cover 118 is placed on top of the cavity wall. A port 120 extends through the cover 118.

The MEMS device 102 includes a diaphragm 136 and a back plate 134 as known to those skilled in the art. Sound energy received through the port 120 moves the diaphragm 136 and as the diaphragm 136 moves an electrical voltage representative of the received signal is created by the MEMS device 104. This voltage is transmitted to the integrated circuit 102 via the wired bonds 122 and 124. The integrated circuit 102 may be any type of integrated circuit, but in some examples performs amplification and noise removal functions. Once processed by the integrated circuit 102, the processed signal is sent out of the integrated circuit 102 by wire bonds 112 and 114 to the conductive pads 108 and 110, then through conductive layers/traces in the substrate 106, and then to a bottom surface 111 of the substrate 106 where a customer can make an electrical connection. For example the microphone assembly 100 may be used in a personal computer or cellular phone and other electronic devices in these systems may couple to the microphone 100.

As shown, the wall 116 forms a cavity 126 with the substrate 106 in which the MEMS device 104 and the integrated circuit 102 are disposed. A front volume 130 is formed between the cover and the MEMS device 104. A back volume 132 is formed on the opposite side of the MEMS device 104.

It will be appreciated that the system of FIG. 1 and FIG. 2 can be a “one piece” system or a “two piece” system. That is, the wall 116 may be integrally formed with the substrate 106, or formed separately from the substrate (and then connected to the substrate).

Filler material 128 is placed (e.g., dispensed, jetted, and so forth) into the cavity 126. The filler material 128 may be a cure-able adhesive to protect integrated circuits and interconnects from light and reduce the front volume. Other examples of filler material are possible. In this example, the filler material 128 is generally flush with the upper surface of the integrated circuit 102 and MEMS device 104 (although not covering the top surface of the MEMS device 104 and likely covering the top surface of the integrated circuit 102). Advantageously, the filler material 128 reduces the front volume 130 and this is beneficial to the operation of the microphone 132.

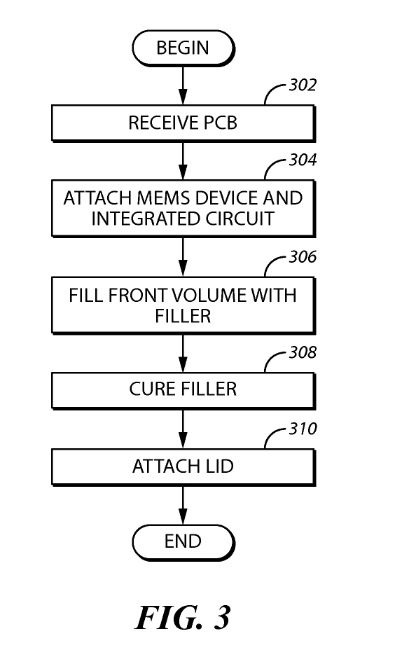

Referring now to FIG. 3, one example of an approach for constructing the devices of FIG. 1, FIG. 2, is described. A step 302, a printed circuit board (PCB) (e.g., a six layer or more open cavity PCB) or substrate is received. At step 304, the MEMS device and the integrated circuit (e.g., an application specific integrated circuit (ASIC)) are placed on the PCB. Attachment of the MEMS and ASIC are made with die attach epoxy, conductive epoxy or other materials. Wire bonds are attached between the MEMS and ASIC and from the ASIC to the PCB.

At step 306, the cavity 106 (between the PCB and the wall) is filled in with curable adhesive. At step 308, the adhesive is cured. At step 310, a lid (e.g., a metal lid) is attached using epoxy or solder. The lid is preferably flat, but might also have some curvature to it.

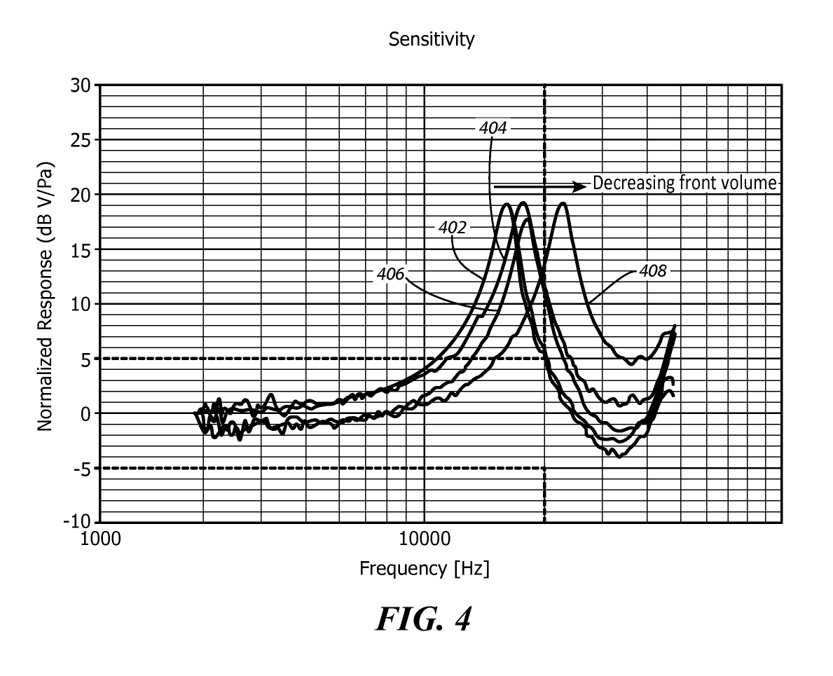

Referring now to FIG. 4, one example of a graph illustrating the beneficial effects of employing the present approaches is described. The x-axis of the graph shows frequency, while the y-axis shows the sensitivity response of a microphone. A first plotting 402, a second plotting 404, a third plotting 406, and a fourth plotting 408 are shown on the graphs. Generally speaking each of the plottings 402, 404, 406, and 408 are plottings for a particular front volume. The front volume of plot 408 is less than that of plot 406, which is less than that of plot 406, which is less than that of plot 402.

It can be seen that as the front volume decreases, the peaks are moved to the right and a linear response curve is achieved over a greater frequency range. This is beneficial because the better the linearity, the better the performance of the microphone, and this is achieved over a greater frequency range.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. An acoustic apparatus, comprising:
a substrate;
a microelectromechanical system (MEMS) device disposed on the substrate, the MEMS device forming a back volume between the MEMS device and the substrate;
an integrated circuit disposed on the substrate;
a cover disposed on the substrate, the cover with a port, the cover forming a cavity in which the MEMS device and the integrated circuit are disposed;
wherein the cover, substrate, MEMS device, and integrated circuit form a front volume;
wherein a filler material is disposed in the cavity to reduce an amount of the front volume that would exist in the absence of the filler material.

2. The acoustic apparatus of claim 1, wherein the filler material is disposed so that its top surface is approximately flush with an upper surface of the MEMS device.

3. The acoustic apparatus of claim 1, wherein the filler material is disposed so that its top surface is approximately flush with an upper surface of the integrated circuit.

4. The acoustic apparatus of claim 1, wherein the filler material comprises an epoxy.

5. The acoustic apparatus of claim 1, wherein the substrate is a printed circuit board.

6. The acoustic apparatus of claim 1, wherein the cover comprises one-piece.

7. The acoustic apparatus of claim 1, wherein the cover comprises a wall and a lid.

8. The acoustic apparatus of claim 7, wherein the lid comprises a metal.

9. The acoustic apparatus of claim 1, wherein the filler material is disposed so that its top surface is above an upper surface of the MEMS device.
